(19) United States
(12) Patent Application Publication
(10) Pub. No.: US 2026/0118547 A1
(43) Pub. Date: Apr. 30, 2026

(54) ADAPTIVE 4D SEISMIC SURVEY DESIGN FOR MONITORING OF CARBON STORAGE SITES

(71) Applicant: Schlumberger Technology Corporation, Sugar Land, TX (US)

(72) Inventors: David Fraser HALLIDAY, Crawley (GB); Massimiliano VASSALLO, Crawley (GB); Michael William BRANSTON, Petaling Jaya (MY); Ran BACHRACH, Houston, TX (US)

(21) Appl. No.: 19/133,248

(22) PCT Filed: Oct. 31, 2024
(86) PCT No.: PCT/US2024/053781

§ 371 Date: May 28, 2025

Related U.S. Application Data
(60) Provisional application No. 63/654,227, filed on May 31, 2024.

(51) Int. Cl. G01V 20/00; G06F 30/28

(52) U.S. Cl. CPC G01V 20/00; G06F 30/28

(57) ABSTRACT

A method for monitoring subterranean hydrocarbon storage sites includes simulating a seismic experiment using a baseline model. The method also includes perturbing the baseline model to produce one or more perturbed baseline models. The method also includes selecting a plurality of candidate acquisition geometries to probe the one or more perturbed baseline models. The method also includes extracting a set of simulated data from the simulated seismic experiment that corresponds to the plurality of candidate acquisition geometries. The method also includes executing a model probing exercise for the extracted set of simulated data for each candidate acquisition geometry and each of the one or more perturbed baseline models.

### CROSS-REFERENCE TO RELATED APPLICATIONS

This application claims priority to U.S. Provisional Patent Application No. 63/654,227, filed on May 31, 2024, which is incorporated by reference.

### BACKGROUND

A reservoir can be a subsurface formation that can be characterized at least in part by its porosity and fluid permeability. As an example, a reservoir may be part of a basin such as a sedimentary basin. A basin can be a depression (e.g., caused by plate tectonic activity, subsidence, etc.) in which sediments accumulate. As an example, where hydrocarbon source rocks occur in combination with appropriate depth and duration of burial, a petroleum system may develop within a basin, which may form a reservoir that includes hydrocarbon fluids (e.g., oil, gas, etc.).

### SUMMARY

A method for monitoring subterranean hydrocarbon storage sites is disclosed. The method includes simulating a seismic experiment using a baseline model. The method also includes perturbing the baseline model to produce one or more perturbed baseline models. The method also includes selecting a plurality of candidate acquisition geometries to probe the one or more perturbed baseline models. The method also includes extracting a set of simulated data from the simulated seismic experiment that corresponds to the plurality of candidate acquisition geometries. The method also includes executing a model probing exercise for the extracted set of simulated data for each candidate acquisition geometry and each of the one or more perturbed baseline models.

A computing system is also disclosed. The computing system includes one or more processors and a memory system. The memory system includes one or more non-transitory computer-readable media storing instructions that, when executed by at least one of the one or more processors, cause the computing system to perform operations. The operations include simulating a seismic experiment using a baseline model. The seismic experiment is a simulated pressure propagation of seismic wavefields and/or a simulated particle velocity propagation of the seismic wavefields in the baseline model. The operations also include generating a set of synthetic data for a range of source locations and a range of receiver locations that correspond to an identified source location and an identified receiver location that respectively are configured to be used in a monitor survey. The operations also include perturbing the baseline model to produce one or more perturbed baseline models. The baseline model is perturbed with a constant slowness to produce a first perturbed baseline model, and with a localized perturbation representative of a defined target to produce a second perturbed baseline model. The operations also include selecting a plurality of candidate acquisition geometries to probe the one or more perturbed baseline models. The candidate acquisition geometries include a subset of the identified source location and the identified receiver location. The operations also include extracting a set of simulated data from the simulated seismic experiment that corresponds to the candidate acquisition geometries. The set of simulated data includes shot gathers and/or receiver gathers that each correspond to the identified source location and the identified receiver location in the candidate acquisition geometries. The operations also include executing a model probing exercise for the extracted set of simulated data for each candidate acquisition geometry and each of the one or more perturbed baseline models.

A non-transitory computer-readable medium is also disclosed. The medium includes instructions that, when executed by one or more processors of a computing system, cause the computing system to perform operations. The operations include simulating a seismic experiment using a baseline model. The seismic experiment is a simulated propagation of seismic wavefields that may be extracted as a pressure or a particle velocity measurement in the baseline model. The operations also include generating a set of synthetic data for a range of source locations and a range of receiver locations that correspond to an identified source location and an identified receiver location that respectively are configured to be used in a monitor survey. The identified source location and the identified receiver location are each modelled first shot gathers or first receiver gathers. The first shot gathers and/or the first receivers gather respectively correspond to a single set or a multicomponent set of seismic data. The operations also include perturbing the baseline model to produce one or more perturbed baseline models. The baseline model is perturbed with a constant slowness to produce a first perturbed baseline model, and with a localized perturbation representative of a defined target to produce a second perturbed baseline model. The baseline model is perturbed with a slowness value from about 0.5% to about 3% of an inverse P-wave velocity of the baseline model. The baseline model is perturbed with the localized perturbation that corresponds to an expected elastic property change in a subsurface formation after injection of carbon dioxide (CO₂). The expected elastic property change is generated through reservoir modelling. The baseline model is perturbed in parallel with simulating the seismic experiment. The operations also include selecting a plurality of candidate acquisition geometries to probe the one or more perturbed baseline models. The candidate acquisition geometries include a subset of the identified source location and the identified receiver location. The operations also include extracting a set of simulated data from the simulated seismic experiment that corresponds to the candidate acquisition geometries. The set of simulated data includes second shot gathers and/or second receiver gathers that each correspond to the identified source location and the identified receiver location in the candidate acquisition geometries. The operations also include executing a model probing exercise for the extracted set of simulated data for each candidate acquisition geometry and each of the one or more perturbed baseline models. The model probing exercise includes determining a data residual from the simulated seismic experiment and the one or more perturbed baseline models. The data residual includes a difference between an output of the simulated seismic experiment and the corresponding set of synthetic data generated in the one or more perturbed baseline models. The model probing exercise also includes determining a full-waveform inversion gradient based upon the data residual. The full-waveform inversion gradient is indicative of how the candidate acquisition geometries illuminate and recover a target perturbation. The operations also include conducting a statistical analysis of a selected number of metrics from the model probing exercise. The statistical analysis includes computing a mean and a standard deviation of the metrics. The metrics include a percentage of a target region illuminated by the candidate acquisition geometries, a root mean square difference between the target perturbation and a recovered perturbation, a cross-correlation coefficient between the target perturbation and the recovered perturbation, an estimated cost of the candidate acquisition geometries, or a combination thereof. The operations also include calculating a confidence value for each candidate acquisition geometry based upon the statistical analysis and/or the metrics. The operations also include ranking each of the candidate acquisition geometries based on the calculated confidence values.

It will be appreciated that this summary is intended merely to introduce some aspects of the present methods, systems, and media, which are more fully described and/or claimed below. Accordingly, this summary is not intended to be limiting.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIG. 1 illustrates a block representation of portions of a computing system that may carry out assorted embodiments of the present disclosure.

FIG. 2 illustrates aspects of a seismic system that may utilize the computing system of FIG. 1 in accordance with various embodiments.

FIG. 3 illustrates portions of a hydrocarbon drilling system that may be employed in some embodiments of the present disclosure.

FIG. 4 illustrates aspects of a hydrocarbon drilling system that may be utilized in assorted embodiments of the present disclosure.

FIG. 5 illustrates portions of a hydrocarbon drilling system that may be employed in various embodiments of the present disclosure.

FIG. 6 illustrates aspects of hydrocarbon environment in which embodiments of the present disclosure may be conducted.

FIG. 7 illustrates portions of a hydrocarbon environment in which assorted embodiments of the present disclosure may be deployed.

FIGS. 8A and 8B respectively illustrate workflow embodiments of the computing system of FIG. 1 operating in the hydrocarbon environments of FIGS. 6 and 7.

FIGS. 9A and 9B respectively illustrate workflow embodiments of the computing system of FIG. 1 operating in the hydrocarbon environments of FIGS. 6 and 7.

FIGS. 10A and 10B respectively illustrate workflow embodiments of the computing system of FIG. 1 operating in the hydrocarbon environments of FIGS. 6 and 7.

FIGS. 11A and 11B respectively illustrate workflow embodiments of the computing system of FIG. 1 operating in the hydrocarbon environments of FIGS. 6 and 7.

FIGS. 12A and 12B respectively illustrate workflow embodiments of the computing system of FIG. 1 operating in the hydrocarbon environments of FIGS. 6 and 7.

FIGS. 13A and 13B illustrate operational data from execution of various embodiments of the computing system of FIG. 1.

FIGS. 14A and 14B respectively illustrate operational data resulting from the computing system of FIG. 1 employed in accordance with some embodiments.

FIGS. 15A and 15B illustrate example data generated by the computing system of FIG. 1 operating in a hydrocarbon environment of FIGS. 6 and 7.

FIGS. 16A and 16B illustrate a flowchart of a method for monitoring subterranean hydrocarbon storage sites.

### DETAILED DESCRIPTION

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits and networks have not been described in detail so as not to unnecessarily obscure aspects of the embodiments.

It will also be understood that, although the terms first, second, etc., may be used herein to describe various elements, these elements should not be limited by these terms. These terms are used to distinguish one element from another. For example, a first object or step could be termed a second object or step, and, similarly, a second object or step could be termed a first object or step, without departing from the scope of the invention. The first object or step, and the second object or step, are both objects or steps, respectively, but they are not to be considered the same object or step.

The terminology used in the description of the invention herein is for the purpose of describing particular embodiments and is not intended to be limiting of the invention. As used in the description of the invention and the appended claims, the singular forms “a,” “an” and “the” are intended to include the plural forms as well, unless the context clearly indicates otherwise. It will also be understood that the term “and/or” as used herein refers to and encompasses any possible combination of one or more of the associated listed items. It will be further understood that the terms “includes,” “including.” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context.

Those with skill in the art will appreciate that while some terms in this disclosure may refer to absolutes, e.g., all of the components of a wavefield, all source receiver traces, each of a plurality of objects, etc., the methods and techniques disclosed herein may also be performed on fewer than all of a given thing, e.g., performed on one or more components and/or performed on one or more source receiver traces. Accordingly, in instances in the disclosure where an absolute is used, the disclosure may also be interpreted to be referring to a subset.

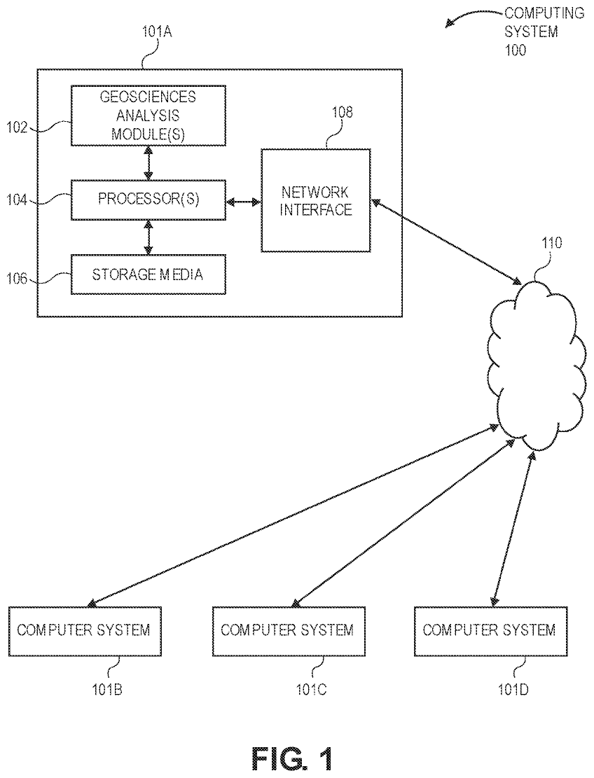

FIG. 1 depicts an example computing system 100 in accordance with some embodiments. The computing system 100 can be an individual computer system 101A or an arrangement of distributed computer systems. The computer system 101A includes one or more geosciences analysis modules 102 that are configured to perform various tasks according to some embodiments, such as one or more methods disclosed herein. To perform these various tasks, geosciences analysis module 102 executes independently, or in coordination with, one or more processors 104, which is (or are) connected to one or more storage media 106. The processor(s) 104 is (or are) also connected to a network interface 108 to allow the computer system 101A to communicate over a data network 110 with one or more additional computer systems and/or computing systems, such as 101B, 101C, and/or 101D (note that computer systems 101B, 101C and/or 101D may or may not share the same architecture as computer system 101A, and may be located in different physical locations, e.g., computer systems 101A and 101B may be on a ship underway on the ocean, while in communication with one or more computer systems such as 101C and/or 101D that are located in one or more data centers on shore, other ships, and/or located in varying countries on different continents). Note that data network 110 may be a private network, it may use portions of public networks, it may include remote storage and/or applications processing capabilities (e.g., cloud computing).

A processor can include a microprocessor, microcontroller, processor module or subsystem, programmable integrated circuit, programmable gate array, or another control or computing device.

The storage media 106 can be implemented as one or more computer-readable or machine-readable storage media. Note that while in the example embodiment of FIG. 1 storage media 106 is depicted as within computer system 101A, in some embodiments, storage media 106 may be distributed within and/or across multiple internal and/or external enclosures of computing system 101A and/or additional computing systems. Storage media 106 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories; magnetic disks such as fixed, floppy and removable disks; other magnetic media including tape; optical media such as compact disks (CDs) or digital video disks (DVDs), BluRays or any other type of optical media; or other types of storage devices. Note that the instructions discussed above can be provided on one computer-readable or machine-readable storage medium, or alternatively, can be provided on multiple computer-readable or machine-readable storage media distributed in a large system having possibly plural nodes and/or non-transitory storage means. Such computer-readable or machine-readable storage medium or media is (are) considered to be part of an article (or article of manufacture). An article or article of manufacture can refer to any manufactured single component or multiple components. The storage medium or media can be located either in the machine running the machine-readable instructions, or located at a remote site from which machine-readable instructions can be downloaded over a network for execution.

It should be appreciated that computer system 101A is one example of a computing system, and that computer system 101A may have more or fewer components than shown, may combine additional components not depicted in the example embodiment of FIG. 1, and/or computer system 101A may have a different configuration or arrangement of the components depicted in FIG. 1. The various components shown in FIG. 1 may be implemented in hardware, software, or a combination of both, hardware and software, including one or more signal processing and/or application specific integrated circuits.

It should also be appreciated that while no user input/output peripherals are illustrated with respect to computer systems 101A, 101B, 101C, and 101D, many embodiments of computing system 100 include computer systems with keyboards, mice, touch screens, displays, etc. Some computer systems in use in computing system 100 may be desktop workstations, laptops, tablet computers, smartphones, server computers, etc.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are included within the scope of protection.

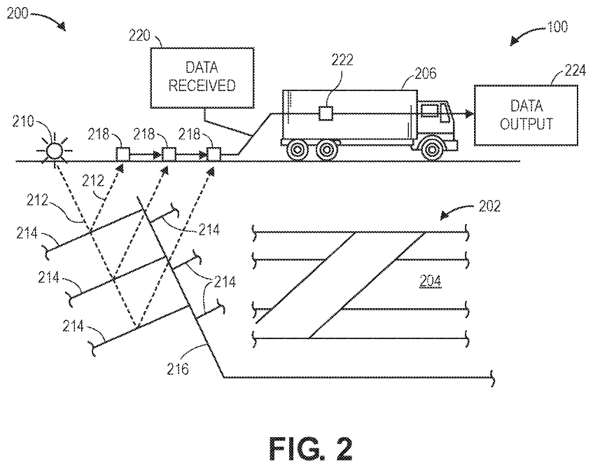

FIGS. 2-7 respectively illustrate simplified, schematic views of oilfield 200 having subterranean formation 202 containing reservoir 204 therein in accordance with implementations of various technologies and techniques described herein.

FIG. 2 illustrates a survey operation being performed by a survey tool, such as seismic truck 206, to measure properties of the subterranean formation. The survey operation is a seismic survey operation for producing sound vibrations. In FIG. 2, one such sound vibration, such as sound vibration 212 generated by source 210, reflects off horizons 214 in earth formation 216. A set of sound vibrations is received by sensors, such as geophone-receivers 218, situated on the earth's surface. The data received 220 is provided as input data to a computer 222 of a seismic truck 206, and responsive to the input data, computer 222 generates seismic data output 224. This seismic data output may be stored, transmitted or further processed as desired, for example, by data reduction.

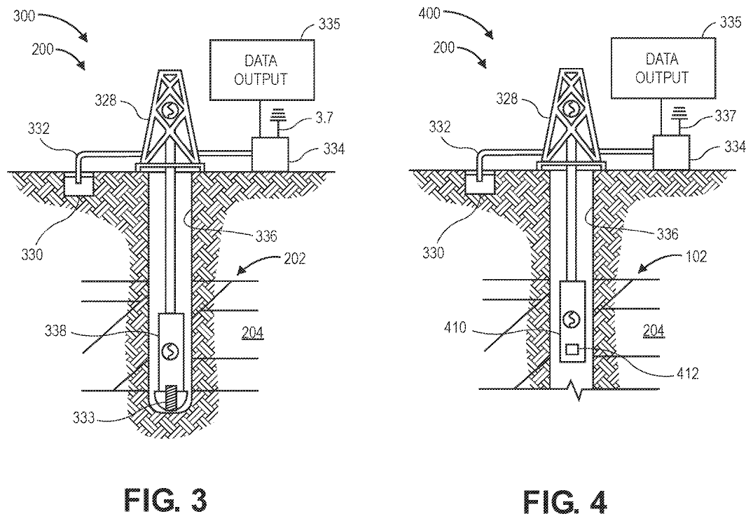

FIG. 3 illustrates a drilling operation being performed by drilling tools 308 suspended by rig 328 and advanced into subterranean formations 202 to form wellbore 336. Mud pit 330 is used to draw drilling mud into the drilling tools via flow line 332 for circulating drilling mud down through the drilling tools, then up wellbore 336 and back to the surface. The drilling mud is typically filtered and returned to the mud pit. A circulating system may be used for storing, controlling, or filtering the flowing drilling mud. The drilling tools are advanced into subterranean formations 202 to reach reservoir 204. Each well may target one or more reservoirs. The drilling tools are adapted for measuring downhole properties using logging while drilling tools. The logging while drilling tools may also be adapted for taking core sample 333 as shown.

Computer facilities may be positioned at various locations about the oilfield 200, such as the surface unit 334, and/or at remote locations. Surface unit 334 may be used to communicate with the drilling tools and/or offsite operations, as well as with other surface or downhole sensors. Surface unit 334 is capable of communicating with the drilling tools to send commands to the drilling tools, and to receive data therefrom. Surface unit 334 may also collect data generated during the drilling operation and produce data output 335, which may then be stored or transmitted.

Sensors (S), such as gauges, may be positioned about oilfield 200 to collect data relating to various oilfield operations as described previously. As shown, sensor (S) is positioned in one or more locations in the drilling tools and/or at rig 328 to measure drilling parameters, such as weight on bit, torque on bit, pressures, temperatures, flow rates, compositions, rotary speed, and/or other parameters of the field operation. Sensors (S) may also be positioned in one or more locations in the circulating system.

Drilling tools 338 may include a bottom hole assembly (BHA) (not shown), generally referenced, near the drill bit, such as within several drill collar lengths from the drill bit. The bottom hole assembly includes capabilities for measuring, processing, and storing information, as well as communicating with surface unit 334. The bottom hole assembly further includes drill collars for performing various other measurement functions.

The bottom hole assembly may include a communication subassembly that communicates with surface unit 334. The communication subassembly is adapted to send signals to and receive signals from the surface using a communications channel such as mud pulse telemetry, electro-magnetic telemetry, or wired drill pipe communications. The communication subassembly may include, for example, a transmitter that generates a signal, such as an acoustic or electromagnetic signal, which is representative of the measured drilling parameters. It will be appreciated by one of skill in the art that a variety of telemetry systems may be employed, such as wired drill pipe, electromagnetic or other known telemetry systems.

Typically, the wellbore is drilled according to a drilling plan that is established prior to drilling. The drilling plan typically sets forth equipment, pressures, trajectories and/or other parameters that define the drilling process for the wellsite. The drilling operation may then be performed according to the drilling plan. However, as information is gathered, the drilling operation may need to deviate from the drilling plan. Additionally, as drilling or other operations are performed, the subsurface conditions may change. The earth model may also need adjustment as new information is collected

The data gathered by sensors (S) may be collected by surface unit 334 and/or other data collection sources for analysis or other processing. The data collected by sensors (S) may be used alone or in combination with other data. The data may be collected in one or more databases and/or transmitted on or offsite. The data may be historical data, real time data, or combinations thereof. The real time data may be used in real time, or stored for later use. The data may also be combined with historical data or other inputs for further analysis. The data may be stored in separate databases, or combined into a single database.

Surface unit 334 may include transceiver 337 to allow communications between surface unit 334 and various portions of the oilfield 200 or other locations. Surface unit 334 may also be provided with or functionally connected to one or more controllers (not shown) for actuating mechanisms at oilfield 200. Surface unit 334 may then send command signals to oilfield 100 in response to data received. Surface unit 334 may receive commands via transceiver 337 or may itself execute commands to the controller. A processor may be provided to analyze the data (locally or remotely), make the decisions and/or actuate the controller. In this manner, oilfield 200 may be selectively adjusted based on the data collected. This technique may be used to optimize (or improve) portions of the field operation, such as controlling drilling, weight on bit, pump rates, or other parameters. These adjustments may be made automatically based on computer protocol, and/or manually by an operator. In some cases, well plans may be adjusted to select optimum (or improved) operating conditions, or to avoid problems.

FIG. 4 illustrates a wireline operation being performed by wireline tool 109 suspended by rig 328 and into wellbore 336 of FIG. 3. Wireline tool 410 is adapted for deployment into wellbore 336 for generating well logs, performing downhole tests and/or collecting samples. Wireline tool 410 may be used to provide another method and apparatus for performing a seismic survey operation. Wireline tool 410 may, for example, have an explosive, radioactive, electrical, or acoustic energy source 412 that sends and/or receives electrical signals to surrounding subterranean formations 202 and fluids therein.

Wireline tool 410 may be operatively connected to, for example, geophones 218 and a computer 222 of a seismic truck 206 of FIG. 2. Wireline tool 410 may also provide data to surface unit 334. Surface unit 334 may collect data generated during the wireline operation and may produce data output 335 that may be stored or transmitted. Wireline tool 410 may be positioned at various depths in the wellbore 336 to provide a survey or other information relating to the subterranean formation 202.

Sensors (S), such as gauges, may be positioned about oilfield 200 to collect data relating to various field operations as described previously. As shown, sensor S is positioned in wireline tool 410 to measure downhole parameters which relate to, for example porosity, permeability, fluid composition and/or other parameters of the field operation.

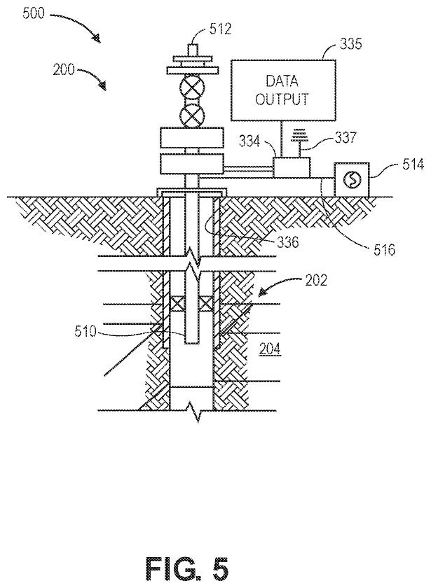

FIG. 5 illustrates a production operation being performed by production tool 510 deployed from a production unit or Christmas tree 512 and into completed wellbore 136 for drawing fluid from the downhole reservoirs into surface facilities 514. The fluid flows from reservoir 204 through perforations in the casing (not shown) and into production tool 510 in wellbore 336 and to surface facilities 514 via gathering network 516.

Sensors (S), such as gauges, may be positioned about oilfield 200 to collect data relating to various field operations as described previously. As shown, the sensor (S) may be positioned in production tool 510 or associated equipment, such as Christmas tree 512, gathering network 516, surface facility 514, and/or the production facility, to measure fluid parameters, such as fluid composition, flow rates, pressures, temperatures, and/or other parameters of the production operation.

Production may also include injection wells for added recovery. One or more gathering facilities may be operatively connected to one or more of the wellsites for selectively collecting downhole fluids from the wellsite(s).

While FIGS. 3-5 illustrate tools used to measure properties of an oilfield, it will be appreciated that the tools may be used in connection with non-oilfield operations, such as gas fields, mines, aquifers, storage or other subterranean facilities. Also, while certain data acquisition tools are depicted, it will be appreciated that various measurement tools capable of sensing parameters, such as seismic two-way travel time, density, resistivity, production rate, etc., of the subterranean formation and/or its geological formations may be used. Various sensors (S) may be located at various positions along the wellbore and/or the monitoring tools to collect and/or monitor the desired data. Other sources of data may also be provided from offsite locations.

The field configurations of FIGS. 2-5 are intended to provide a brief description of an example of a field usable with oilfield application frameworks. Part of, or the entirety, of oilfield 100 may be on land, water, and/or sea. Also, while a single field measured at a single location is depicted, oilfield applications may be utilized with any combination of one or more oilfields, one or more processing facilities and one or more wellsites.

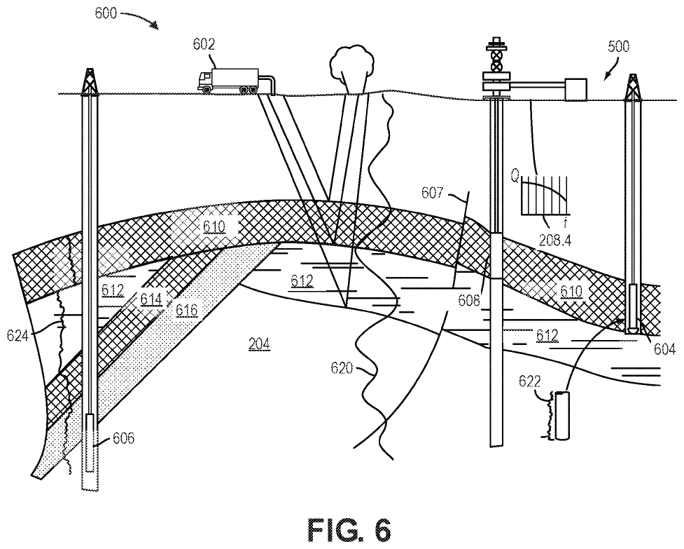

FIG. 6 illustrates a schematic view, partially in cross section of oilfield 600 having data acquisition tools 602, 604, 606 and 608 positioned at various locations along oilfield 600 for collecting data of subterranean formation in accordance with implementations of various technologies and techniques described herein. Data acquisition tools 602/604/606/608 may be the same as data acquisition tools depicted FIGS. 2-5, respectively, or others not depicted. As shown, data acquisition tools 602, 604, 606, and 608 generate data plots or measurements 610, 612, 614, and 616 respectively. These data plots are depicted along oilfield 600 to demonstrate the data generated by the various operations.

Data plots 620, 622, 624, and 626 are examples of static data plots that may be generated by data acquisition tools 602, 604, 606, and 608, respectively; however, it should be understood that data plots 620, 622, 624, and 626 may also be data plots that are updated in real time. These measurements may be analyzed to better define the properties of the formation(s) and/or determine the accuracy of the measurements and/or for checking for errors. The plots of each of the respective measurements may be aligned and scaled for comparison and verification of the properties.

Static data plot 620 is a seismic two-way response over a period of time. Static plot 622 is core sample data measured from a core sample of the formation 204. The core sample may be used to provide data, such as a graph of the density, porosity, permeability, or some other physical property of the core sample over the length of the core. Tests for density and viscosity may be performed on the fluids in the core at varying pressures and temperatures. Static data plot 624 is a logging trace that typically provides a resistivity or other measurement of the formation at various depths.

A production decline curve or graph 626 is a dynamic data plot of the fluid flow rate over time. The production decline curve typically provides the production rate as a function of time. As the fluid flows through the wellbore, measurements are taken of fluid properties, such as flow rates, pressures, composition, etc.

Other data may also be collected, such as historical data, user inputs, economic information, and/or other measurement data and other parameters of interest. As described below, the static and dynamic measurements may be analyzed and used to generate models of the subterranean formation to determine characteristics thereof. Similar measurements may also be used to measure changes in formation aspects over time.

The subterranean structure 204 has a plurality of geological formations 610, 612, 614, and 616. As shown, this structure has several formations or layers, including a shale layer 610, a carbonate layer 612, a shale layer 614 and a sand layer 616. A fault 607 extends through the shale layer 610 and the carbonate layer 612. The static data acquisition tools are adapted to take measurements and detect characteristics of the formations.

While a specific subterranean formation with specific geological structures is depicted, it will be appreciated that oilfield 600 may contain a variety of geological structures and/or formations, sometimes having extreme complexity. In some locations, typically below the water line, fluid may occupy pore spaces of the formations. Each of the measurement devices may be used to measure properties of the formations and/or its geological features. While each acquisition tool is shown as being in specific locations in oilfield 600, it will be appreciated that one or more types of measurement may be taken at one or more locations across one or more fields or other locations for comparison and/or analysis.

The data collected from various sources, such as the data acquisition tools of FIG. 6, may then be processed and/or evaluated. Typically, seismic data displayed in static data plot 620 from data acquisition tool 602 is used by a geophysicist to determine characteristics of the subterranean formations and features. The core data shown in static plot 622 and/or log data from well log 624 are typically used by a geologist to determine various characteristics of the subterranean formation. The production data from graph 626 is typically used by the reservoir engineer to determine fluid flow reservoir characteristics. The data analyzed by the geologist, geophysicist and the reservoir engineer may be analyzed using modeling techniques.

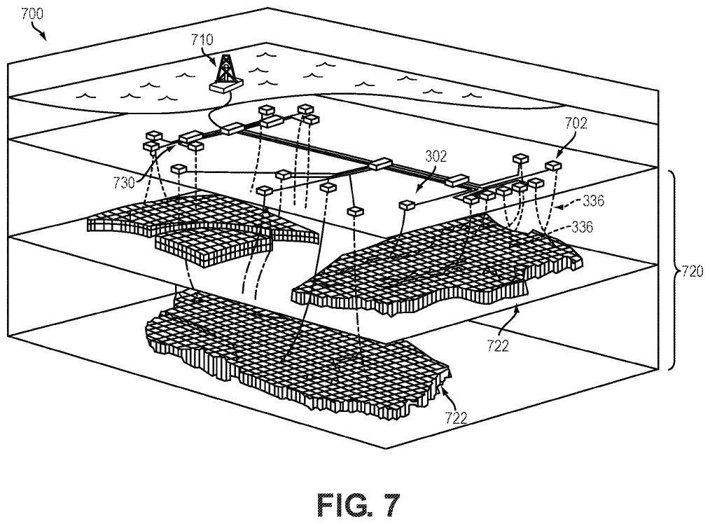

FIG. 7 illustrates an oilfield 700 for performing production operations in accordance with implementations of various technologies and techniques described herein. As shown, the oilfield has a plurality of wellsites 702 operatively connected to central processing facility 710. The oilfield configuration of FIG. 7 is not intended to limit the scope of the oilfield application system. Part, or all, of the oilfield may be on land and/or sea. Also, while a single oilfield with a single processing facility and a plurality of wellsites is depicted, any combination of one or more oilfields, one or more processing facilities and one or more wellsites may be present.

Each wellsite 702 has equipment that forms wellbore 336 into the earth. The wellbores extend through subterranean formations 720 including reservoirs 722. These reservoirs 722 contain fluids, such as hydrocarbons. The wellsites draw fluid from the reservoirs and pass them to the processing facilities via surface networks 730. The surface networks 730 have tubing and control mechanisms for controlling the flow of fluids from the wellsite to processing facility 710.

Attention is now directed to methods, techniques, and workflows for planning, forecasting, and/or optimizing production related systems (e.g., model selections, reservoir maps, wells, etc.) in accordance with some embodiments. Some operations in the processing procedures, methods, techniques, and workflows disclosed herein may be combined and/or the order of some operations may be changed. Those with skill in the art will recognize that in the geosciences and/or other multi-dimensional data processing disciplines, various interpretations, sets of assumptions, and/or domain models such as velocity models, may be refined in an iterative fashion; this concept is applicable to the procedures, methods, techniques, and workflows as discussed herein. This iterative refinement can include use of feedback loops executed on an algorithmic basis, such as at a computing device (e.g., computing system 100, FIG. 1), and/or through manual control by a user who may make determinations regarding whether a given step, action, template, or model has become sufficiently accurate.

Each geological carbon dioxide (CO₂) storage site may require a measurement, monitoring and verification (MMV) plan. The plan can be split into two objectives. For example, conformance, such as tracking of the CO₂ plume and the pressure envelope, and containment, such as monitoring to demonstrate the absence of identified risks, like cap-rock leaks, and leakage along faults.

A primary technology to address 3D spatial conformance is time-lapse, four-dimensional (4D) seismic, which utilize both using borehole and surface measurements. The costs associated with the acquisition, processing, and interpretation of time-lapse seismic data are high. However, the objectives of CO₂ monitoring may be different from those of conventional reservoir monitoring. For example, while the objective of a conventional 4D study may be to infer changes to the rock and fluid properties of the subsurface, such as seismic velocities, density, fluid saturation, porosity, and permeability. The objective of 4D monitoring of a CO₂ site may be detection and localization of the CO₂ plume. There is likely to be significant data redundancy when using conventional full-coverage, high-density time-lapse seismic for CO₂ storage site monitoring.

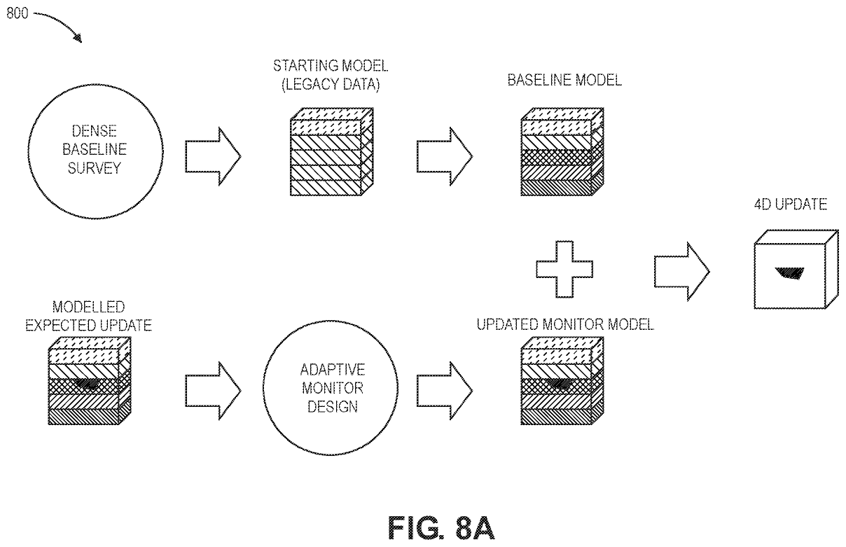

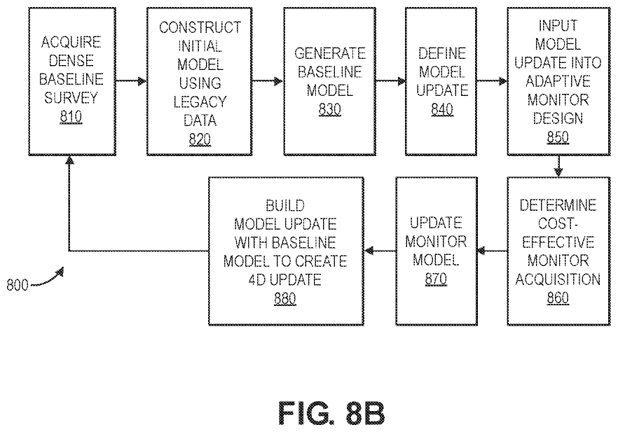

In an embodiment, a workflow is disclosed to determine the minimum seismic acquisition effort to achieve a given monitoring objective, as conveyed in FIGS. 8A and 8B. The monitoring objective may be to confirm that the behavior of the plume conforms to the MMV plan, or it may be to demonstrate the absence of risks identified in the plan. In FIGS. 8A and 8B, aspects of a time-lapse carbon capture and storage (CCS) monitoring workflow 800 are illustrated. A dense baseline seismic survey is acquired in step 810 at the beginning of the CCS project. Legacy data, such as seismic and well log information, are used to construct an initial sub-surface model in step 820, that is then updated, such as with full-waveform inversion, to generate a detailed baseline subsurface model in step 830.

A target model update is then defined in step 840, which may be a modelled prediction of the CO₂ plume location or an identified risk to be monitored. The modelled update is input to the adaptive monitor design in step 850 to determine the most cost-effective monitor acquisition in step 860, given the current understanding of the subsurface model. The sparse monitor survey is updated in step 870 and then used to build a model update on top of the baseline model in step 880, which provides a 4D update. The process can be repeated at future time steps using the updated velocity models, or when new risks are identified.

It is assumed that as part of the MMV planning process, a subsurface dynamic model is available, and that subsurface simulations, such as reservoir modelling and rock physics, has been carried out to predict the expected behavior of the plume through the lifecycle of the CO₂ storage site, as well as potential containment risk events that may occur.

The simulated plume behavior and/or associated risk events can then be used to define targeted changes in a model probing exercise, where synthetic seismic data are generated for a baseline seismic property model, such as P-wave velocity. S-wave velocity, and density, which are used to probe the ability of different candidate acquisition geometries to illuminate and resolve/detect the targeted change. This probing exercise provides metrics, such as illumination, resolution, and detectability, that can be used to determine the minimum seismic acquisition effort, along with associated processing techniques, required to detect and localize the targeted change and update the seismic property model.

This model probing study can then be repeated through the life of a CO₂ storage site, as the subsurface model is updated, and further risks are identified. In this way, the monitoring design is adaptive, and the cost is proportional to the actual plume behavior and associated risks.

In a non-limiting embodiment, certain characteristics of seismic full-waveform inversion (FWI) are employed, in particular FWI's ability to connect the data domain, such as seismic gathers, to the model domain, such as subsurface wave propagation velocities, via back propagation of data residuals into the model. This back propagation yields the FWI gradient, which indicates how the current model needs to change to better fit the data.

If the true subsurface model is well understood, or in the context of time-lapse seismic, a reliable baseline sub-surface model is present, synthetic experiments can be carried out to probe that model, via FWI, using different seismic acquisition geometries. For example, the illumination of the subsurface may be assessed, as well as the ability to detect/resolve different targeted changes. Further, the uncertainty in those different measures may be assessed from both a model uncertainty and data uncertainty point of view.

It may be assumed that an initial model building exercise has been carried out at the start of the monitoring project. This may be a full coverage, high density, seismic survey that is used to build a baseline model using conventional seismic velocity model building techniques, such as FWI. It may also be assumed that at the outset of the project, during the MMV planning phase, the expected behavior of the plume within this baseline, or the best available sub-surface model, has been modelled, as well as any potential hi-risk events that may need to be monitored for. Using knowledge of these expected changes and potential risk events, a synthetic probing study is carried out to connect the ability to detect and localize these subsurface changes to the seismic acquisition effort. Two types of probing studies may be carried out. The first is an illumination probing study, and the second is a target probing study.

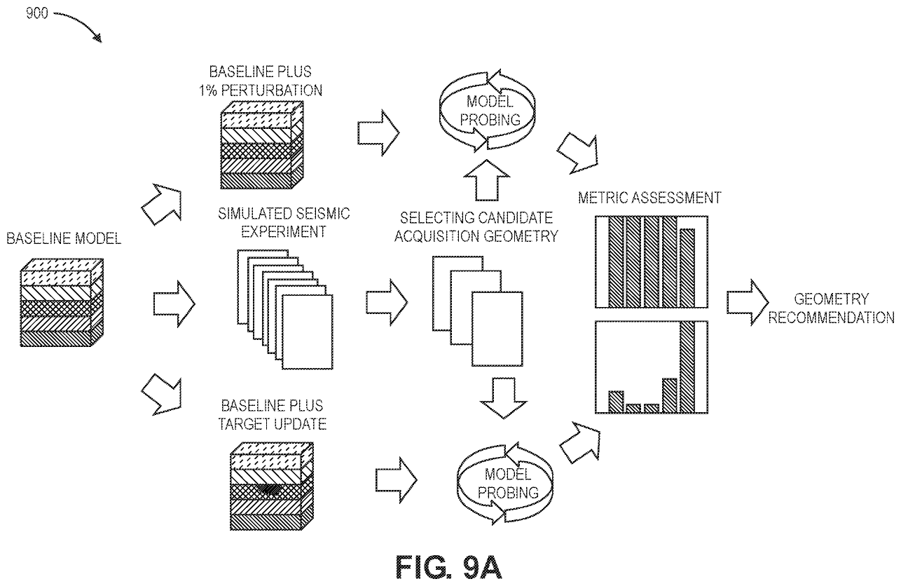

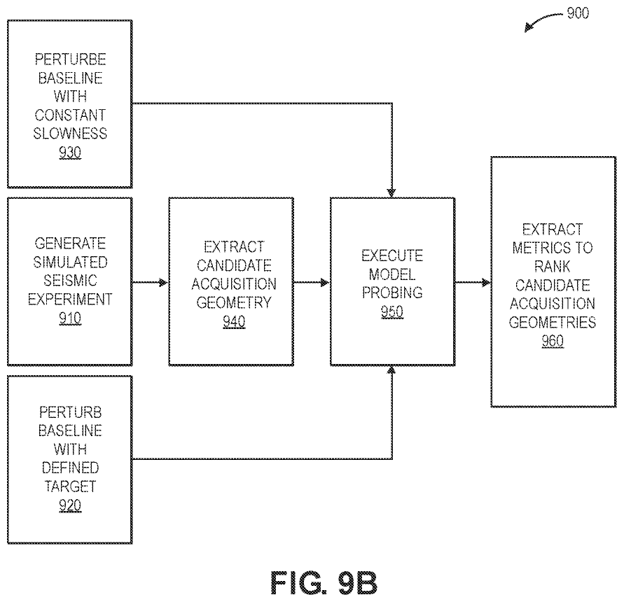

FIGS. 9A and 9B respectively illustrate aspects of an example workflow 900. The starting point for the probing studies is to generate a high density (source and receiver) synthetic dataset. For example, this may use the same source and receiver coverage as the full coverage baseline survey. Simulated seismic data are created using the baseline model in step 910, such as a smoothed version of that model. This baseline model is then perturbed in different ways. First, step 920 provides a localized perturbation representative of the defined target that is applied to allow detectability and resolution to be assessed. Second, a constant slowness perturbation, such as 1%, 5%, or 10%, is applied to allow the illumination of different monitor surveys to be assessed. From the dense simulated seismic data, data corresponding to a candidate acquisition geometry is extracted in step 940, and for each of the perturbed models, a model probing exercise is carried out in step 950.

In the non-limiting embodiments conveyed in FIGS. 9A and 9B, the adaptive design workflow 900 finds the most cost-effective acquisition geometry to monitor a defined target, such as an expected update or risk to be monitored. A baseline model, or the best available sub-surface model, may then be used by step 910 to generate a simulated seismic experiment for a dense seismic acquisition. This baseline model is perturbed in steps 920 and 930 to respectively apply a constant slowness perturbation and a localized perturbation representative of the defined target. From the dense simulated seismic data, a candidate acquisition geometry is extracted in step 940, and for each of the perturbed models, a model probing exercise is carried out, in step 950, by running a single inversion of full-waveform inversion. The model perturbation recovered by full-waveform inversion is then measured against the true model perturbation to allow for the extraction of metrics in step 960 to rank the candidate acquisition geometries, which provides an assessment of the most cost-effective geometry that meets the monitoring objective.

The model probings conducted in step 950 may resemble an iteration of FWI. In the model probing loop, a perturbed version of the simulated data is recreated from the perturbed model. The data residual is calculated, such as by differencing the two simulated datasets or computing travel-time differences. This data residual contains the changes due to the perturbation that was introduced. By back-propagating this residual into the perturbed model, the full-waveform inversion gradient is computed that attempts to correct for the perturbation that was made. The model perturbation recovered by the model probing is measured against the true model perturbation, which allows metrics to be extracted to rank the candidate acquisition geometries. For each model perturbation and each candidate geometry an assessment can be made of whether that geometry allows the monitoring objective to be met.

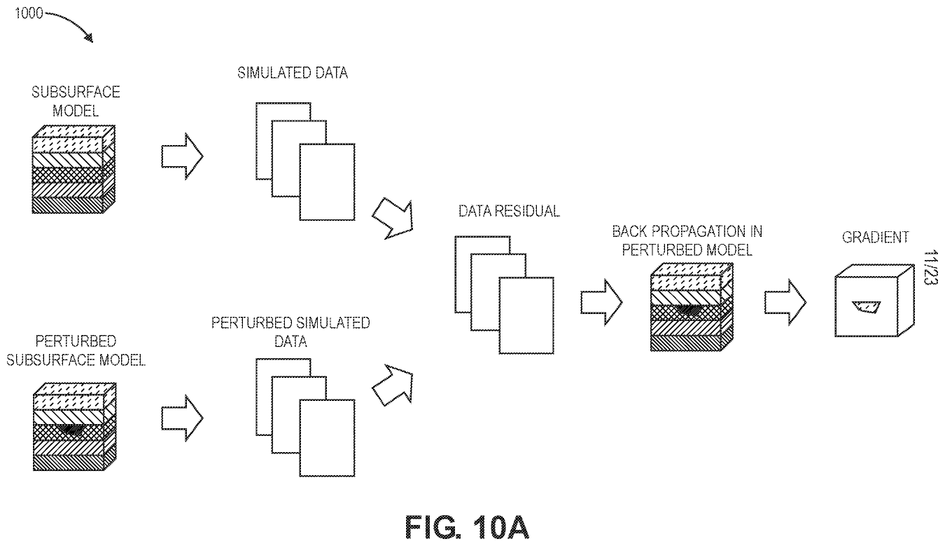

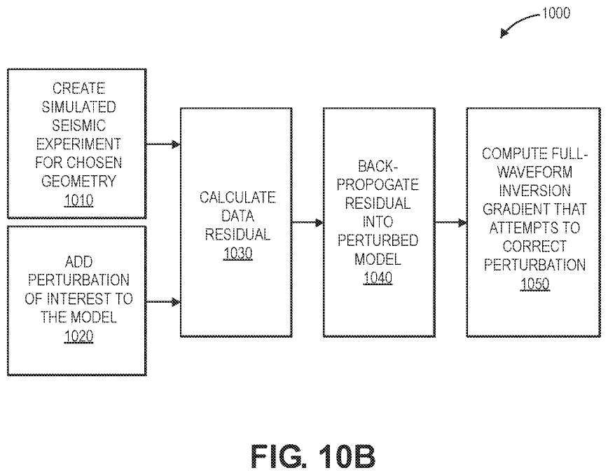

FIGS. 10A and 10B respectively illustrate a single pass of the model probing workflow 1000 that employs a single iteration of full-waveform inversion. For a given subsurface model, which may be the baseline model in a 4D seismic project, a simulated seismic experiment is created in step 1010 for a chosen acquisition geometry. A perturbation of interest is added to the model in step 1020, and a perturbed version of the simulated data are recreated from this model. The data residual is calculated in step 1030, such as by differencing the two simulated datasets or computing travel-time differences. This residual contains the changes due to the perturbation that was introduced. By back-propagating this residual into the perturbed model in step 1040, the full-waveform inversion gradient is computed in step 1050 that attempts to correct for the perturbation that was made. In this way, for a given model perturbation and survey geometry, the ability of the imaging system to illuminate, detect, and resolve that perturbation may be determined.

To assess the illumination, a constant slowness perturbation, such as 1%, is added to the model used to generate the synthetic dataset. A single iteration of full-waveform inversion is then carried out using the synthetic dataset and the constant slowness perturbed model as input. This gradient resulting from this iteration of full-waveform inversion then attempts to correct the constant slowness perturbation. If the sub-surface illumination of the survey is perfect, then constant slowness will be recovered correctly. The degree to which this constant slowness is recovered can be used as a measure of how the sub-surface is illuminated by the acquisition geometry. The illumination can be expressed as a percentage of the recovered change to the true change, as shown in equation 1:

$$illumination ( x , y , z ) = 100 * p e r {t}_{e s t} ( x , y , z ) / {pert}_{true} ( x , y , z ) \qquad ( Equation 1 )$$

The illumination has the same dimensions as the model, and a lower threshold can be set to assess where the model is sufficiently illuminated, as shown in equation 2.

$$( Equation 2 )$$

$$illu m i n a t i o {n}_{t} ( x , y , z ) = \{ \begin{matrix}1 if illumination ( x , y , z ) > threshold \\ 0 if illumination ( x , y , z ) \leq threshold\end{matrix}$$

An illumination metric for the model, and the given acquisition geometry, can then be computed as the percentage of model cells (x,y,z) within a target region of interest, as defined by the area where changes or risks are expected to occur, that are illuminated above the chosen threshold, as shown in equation 3:

$$ill ( model , geometry ) = \frac{1}{N} {\sum }_{( x , y , z ) ∈ target} illuminatio {n}_{t} ( x , y , z ) \qquad ( Equation 3 )$$

Where N represents the number of model cells in the target region.

The illumination metric indicates whether the acquired data are sensitive to changes in different regions of the subsurface. A high illumination metric indicates that for the given subsurface and acquisition geometry we have sensitivity to changes in the subsurface in the target region.

This illumination sensitivity does not indicate the spatial extent or the magnitude of subsurface change we may be able to detect, or whether a change can be adequately resolved. To accomplish this, a second perturbation study is conducted, where rather than using a constant slowness perturbation, a local perturbation is utilized in the model that corresponds to the expected change in the sub-surface, and/or the potential changes that may occur as the result of an identified risk occurring.

The same process is carried out, with an iteration of full-waveform inversion attempting to correct for the perturbation that was made to the model. In this case, the shape, size, and magnitude of the recovered perturbation can be compared with the true perturbation to assess our ability to resolve the change. One way to do this is to use two-dimensional (2D) cross-correlation of the true perturbation versus the recovered perturbation. From the 2D cross-correlation, the correlation coefficient (cc) may be extracted, with a value of 1 corresponding to perfect recovery of the shape of the perturbation. A spatial shift (x) may be extracted to determine if the perturbation is recovered in the correct location. A combined detectability or resolution measure can then be constructed, as shown by equation 4:

$$res ( model , geometry ) = x * ( 1 - c c ) \qquad ( Equation 4 )$$

The resolution metric has a value of 0 when the perturbation is recovered correctly, with higher values corresponding to poorer resolution/detectability. There are many other measures of similarity that may be used. For example, the sum of square differences may be considered, which would also consider regions where the estimated perturbation indicates a change, but where there is no change in the true perturbation. As a result, the recovered perturbation may be classified as correct/incorrect and the statistical classification methods, such as confusion matrices, allow the recovered perturbation to be scored.

For each model change of interest, the above process can be repeated for different geometries, and the metrics can be used to determine the sparsest geometry, such as the most cost-effective, to detect and/or localize the required change in the subsurface. An exhaustive search of all possible geometries may be prohibitively expensive. In contrast, using a set of template geometries, such as different source density and coverage evaluated for different receiver systems, are considered more practical. Geometries where the metrics fall below acceptable values are rejected, and the most cost-effective of the remaining set can be chosen.

The third consideration is the uncertainty in the localization and detection abilities of different acquisition geometries. Uncertainty in full-waveform inversion has been studied to measure the uncertainty in full-waveform inversion velocity updates. While such approaches are likely to be valuable when assessing the actual output of CO₂ monitoring surveys, such as to assess the probability of whether a given velocity change corresponds to CO₂ or not, FWI is a very non-linear process, which is challenging to assess uncertainty during a planning/design stage.

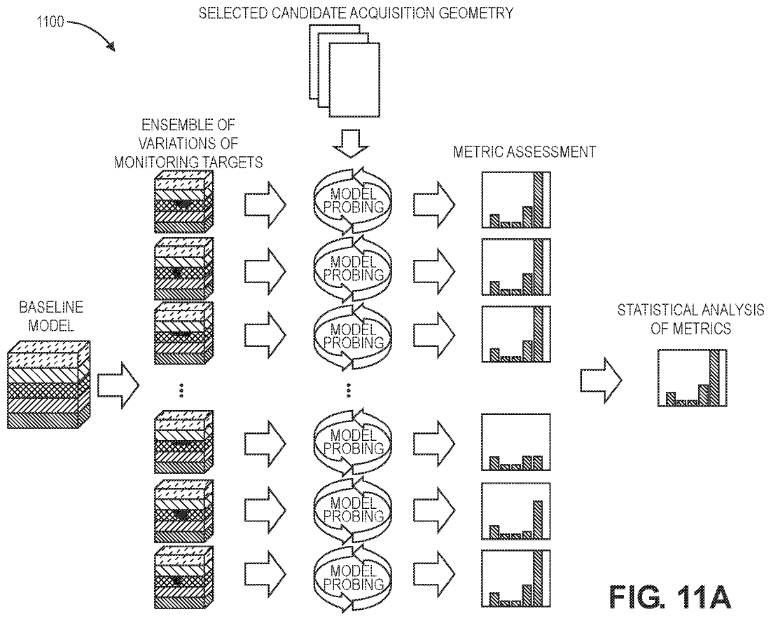

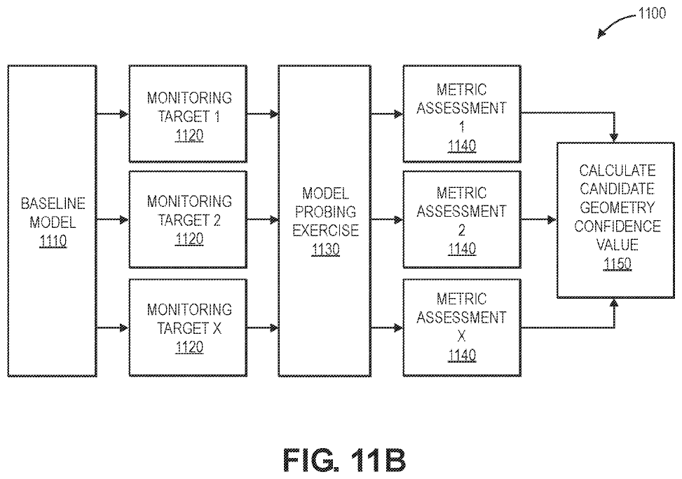

An alternative approach to quantifying the uncertainty as part of an adaptive design workflow is to consider an ensemble of potential changes in the subsurface, as illustrated in FIGS. 11A and 11B, by considering different evolutions of the plume, or by considering different ways in which the identified risks may occur. For each case of interest, an ensemble of models allows for simple statistical measures, such as the mean and standard deviation of the corresponding metrics, to provide an additional uncertainty metric to be used in assessing the different adaptive geometries.

FIGS. 11A and 11B respectively convey an extended workflow 1100 where different realizations of the defined target are generated to provide an ensemble of models that are assessed using the model probing exercise. As shown, a baseline model acquired, or generated, in step 1110 allows for an ensemble of monitoring target variations to be evaluated. It is noted that any number (X) of targets may be concurrently, or sequentially, analyzed in step 1120 to allow one or more model probing exercises to be conducted in step 1130. Statistical analysis of a selected number (X) of metrics in step 1140 can then allow for a measure of confidence/uncertainty in the ability of each candidate geometry to meet the monitoring objective to be calculated in step 1150.

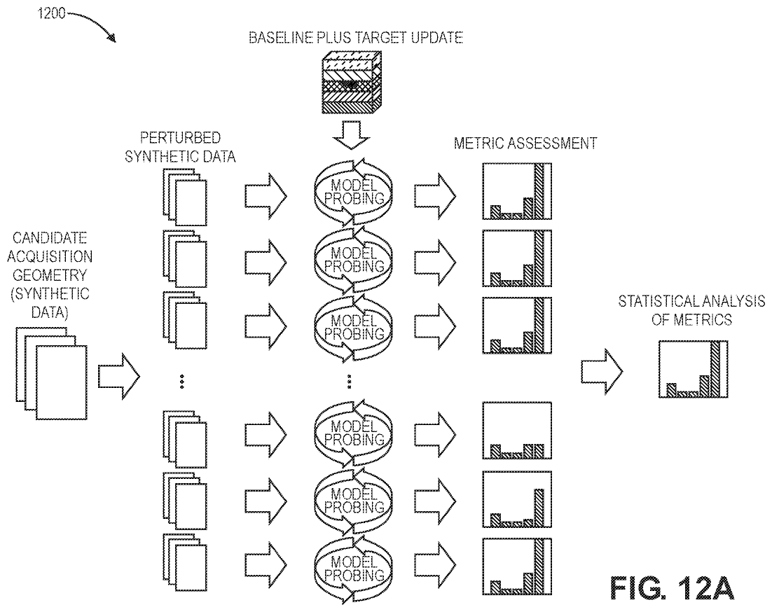

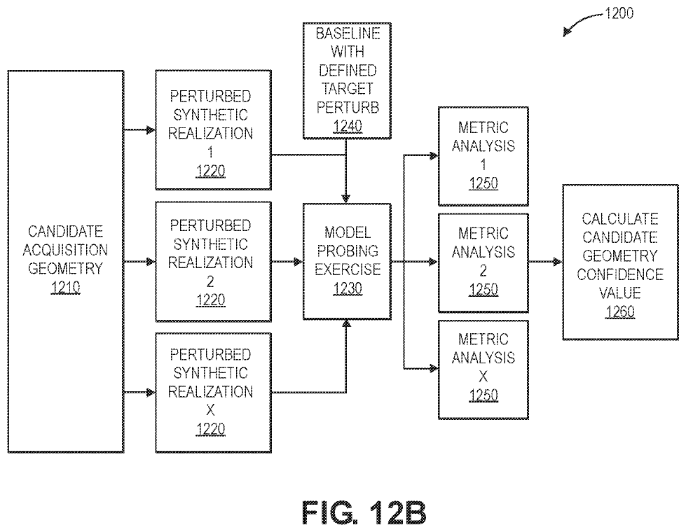

Another, non-limiting, embodiment that assesses uncertainty addresses the uncertainty caused by changes, such as four-dimensional perturbations, away from a subterranean reservoir, as illustrated by FIGS. 12A and 12B. For example, embodiments might include introducing errors in the placement of sources or receivers, sea-level changes, and/or changes in the overburden. In this way, experimental uncertainty in the adaptive design may be assessed, as well as model uncertainty.

FIGS. 12A and 12B respectively illustrate an extended workflow 1200 carried out in accordance with various embodiments to create different realizations of the synthetic monitoring experiment. Initially, a candidate acquisition geometry is selected in step 1210 before a number (X) of separate synthetic realizations are perturbed in step 1220. For example, the different realizations may add positional errors to source and/or receiver locations, add noise, and/or vary overburden conditions. The respective realizations are then subjected to one or more model probing exercises in step 1230. Such exercises, in step 1230, may have additional input in the form of a target perturbation of a baseline model generated in step 1240.

In step 1250, statistical analysis of the metrics from the model probing exercises in step 1230 can then provide a measure of confidence/uncertainty in the ability to meet the monitoring objective in the presence of different types of 4D noise. These probing studies can be repeated for simulated subsurface changes at different time steps in the lifecycle of the CO₂ storage site. This allows the resolution/detectability metrics to be assessed over time, which will allow the time interval between different monitor surveys to be planned and optimized. As a result of the analysis of the assorted metrics derived from probing different realizations, step 1260 may accurately calculate one or more candidate geometry confidence values.

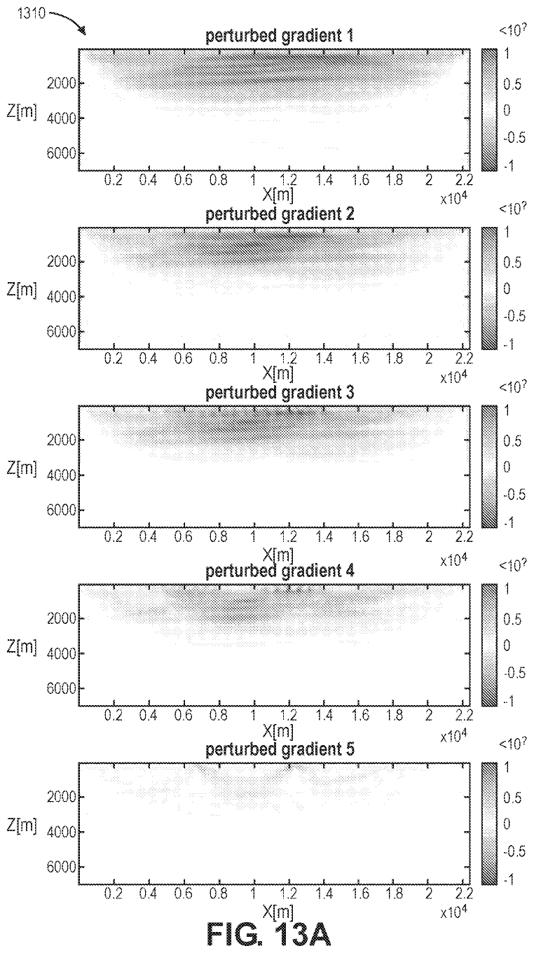

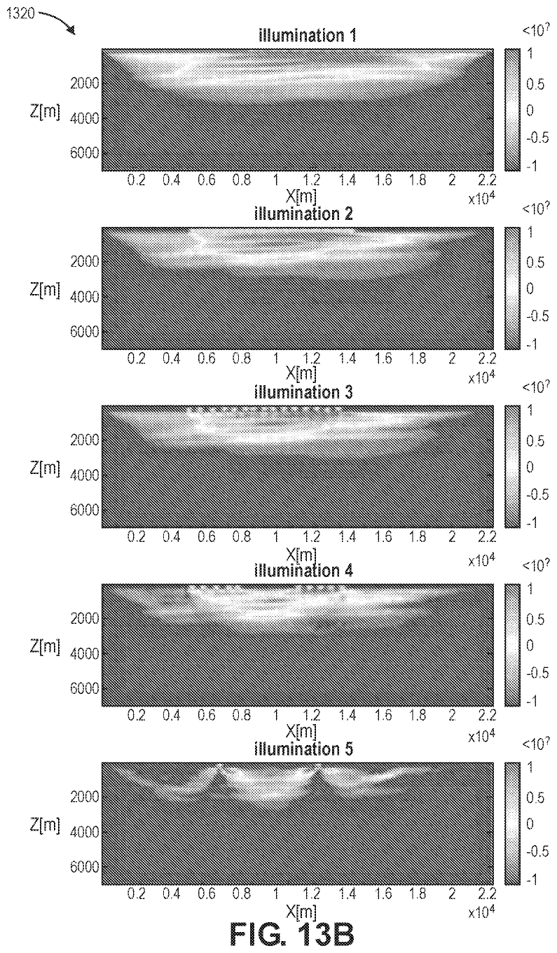

FIGS. 13A and 13B illustrate statistical information pertaining to an example adaptive 4D seismic survey system 1300 execution of assorted embodiments. The model shown in FIGS. 13A and 13B may be considered probing for a 2D model based on a southern north-sea CO₂ injection scenario. It is assumed that the receiver system is fixed, such as an S-DAS cable trenched in the seabed. A smoothed version of the true baseline model is used as the unperturbed model. In the first experiment a 1% slowness perturbation is added to the model, and the full-waveform inversion gradient is computed for each of a set of 5 different geometries. An inner mute is applied to the synthetic data to focus the probing on the diving waves. These gradients 1310 are shown in FIGS. 13A and 13B from top to bottom with stars indicating source positions. The gradients 1310 respectively correspond with different seismic shots, such as 180 dense shots; 73 dense shots; 15 sparse shots; 10 sparse shots and 2 sparse shots.

FIGS. 13A and 13B additionally show the ratio of this recovered perturbation, after scaling, to the true perturbation. It is noted that a value of 1.0 is perfect illumination while a value of 0.0 has no illumination.

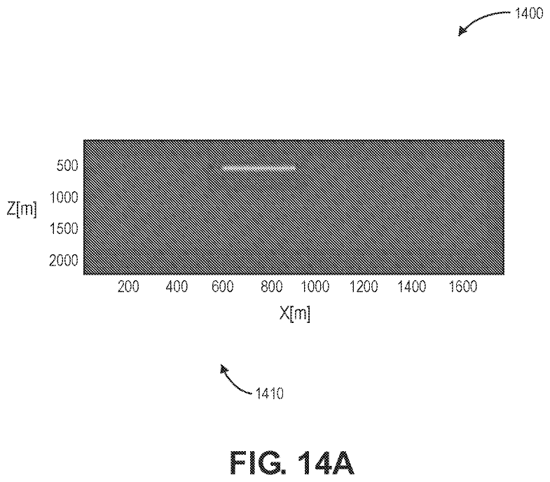

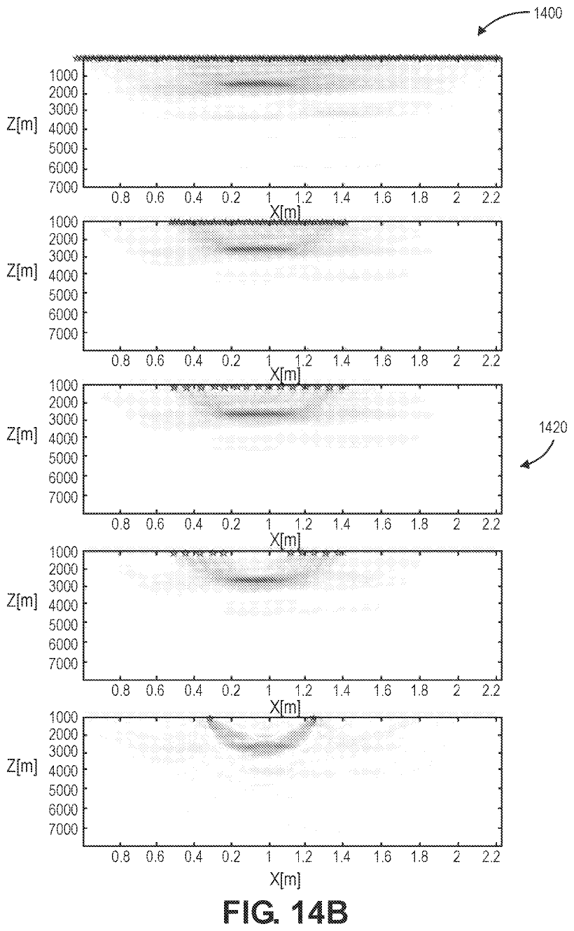

A target perturbation is then added to the model, as illustrated by the example operational data 1400 in FIGS. 14A and 14B, and the process is repeated to assess the ability to detect and resolve that perturbation. The perturbation 1410 is shown, which corresponds with a thin slab. It is noted that in practice, this is likely to be a modelled/simulated change, such as either a predicted change due to injection or a change that represents a risk to be monitored. The gradients 1420 from the model probing exercise, such as from the same set of geometries shown in FIGS. 13A and 13B, are employed. To the eye, each of the first four geometries does a similar job of recovering the perturbation. However, with the fifth geometry, which has 2 shots, sensitivity is shown, but apparently lacking in resolution.

To clarify, the perturbation 1410 is a target velocity perturbation that is added to the baseline model. As shown with the plotted gradients 1420, a 2D example of diving-wave full-waveform inversion gradient attempting to recover the target perturbation 1410. From top to bottom in FIGS. 13A and 13B: 180 dense shots; 73 dense shots; 15 sparse shots; 10 sparse shots; and 2 spare shots were utilized while the receiver configuration is fixed, which mimic the S-DAS trenched in the seabed.

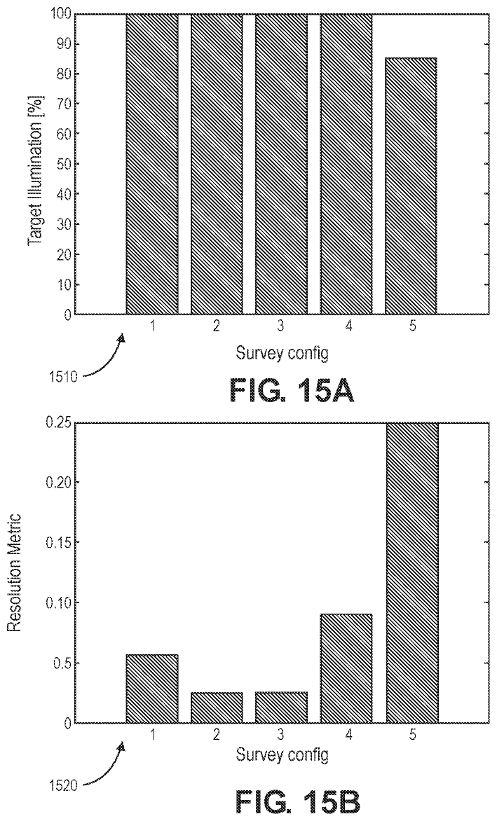

The illumination metric is computed from the plots 1320 in FIGS. 13A and 13B, for the target perturbed region 1410. This is plotted 1510 in FIG. 15A, where we see that each of the first four survey configurations provides full illumination of the target region. With the fifth configuration, with two shots, not providing adequate illumination, the resolution metric 1520 is plotted in FIG. 15B, with similar values again for the first four geometries, and higher values for the fifth. The metrics indicate that the fourth geometry, with 10 shots, can provide similar illumination and resolution of the target as the densest, and most costly, geometry.

In other words, the graphs of FIG. 15A convey the illumination metric 1510 from the results of illumination data 1320 for the perturbed target region 1410. The graph 1520 of FIG. 15B conveys a resolution/detectability metric measured using 2D cross-correlations for the results shown by the data 1420. While illumination and resolution metrics drop off for the bottom plot of data 1420, a significant sensitivity to the perturbation may remain. The current set of criteria are designed to assess the ability to resolve the change, but if the objective was simply to detect the change or identify the edge of the plume in the horizontal plane, then by incorporating knowledge of the subsurface, such as location of top-reservoir, then this result may be of interest. This would require a different set of metrics based on the intended objective of the monitoring.

It is noted that if a metric, such as the sample-by-sample difference, been used, the relatively high values in this bottom display away from the change would have results in a worse ranking that the other figures. The assorted workflows described above specifically address the ability of full-waveform inversion to illuminate and detect changes in a known subsurface model using different acquisition geometries. It should be noted that FWI is not the only candidate approach to monitor for changes in the subsurface, and that the method above could also be tailored for other approaches. In fact, the method may be able to inform which monitoring/detection method is most appropriate for monitoring a given risk or change at a specific time. For example, a method to track the CO₂ plume front, using time delays detected from sparse shots acquired over the storage site. Since it is possible to back-propagate time delays in full waveform inversion, embodiments of the workflows described here could be adapted to determine whether it is possible to detect changes in the subsurface using time delays.

The examples above are based on 2D (in-line) datasets extracted from a 3D modelling study. While 3D simulation is more realistic than 2D, the computational cost of evaluating the performance of many 3D models and acquisition geometries may be high, and in this case 2D simulations may be preferred during the initial planning phase where many scenarios need to be considered. As such, 3D models may be considered as the understanding of the subsurface matures and less scenarios are required.

The examples above consider the use of diving waves, these are waves that turn through the sub-surface due to velocity gradients. One benefit of using diving waves is that the pre-processing requirements are less demanding than when using the full wavefield, for example coherent noise modes like surface waves or multiples can simply be muted out. Reflected waves may provide better vertical resolution than the diving waves alone, but at the cost of additional sampling and pre-processing to account for noise modes that need to be removed. It may be desirable to assess both the use of diving waves and reflections in the model probing studies, to quantify any potential uplift.

Another consideration is the different types of seismic acquisition. The most appropriate acquisition may change through the life of a project. For example, in early phases of a storage project a monitor well may be sufficient to track the plume, but as the plume grows, surface seismic may be needed to provide larger spatial coverage.

While any discussion of or citation to related art in this disclosure may or may not include some prior art references, applicant neither concedes nor acquiesces to the position that any given reference is prior art or analogous prior art.

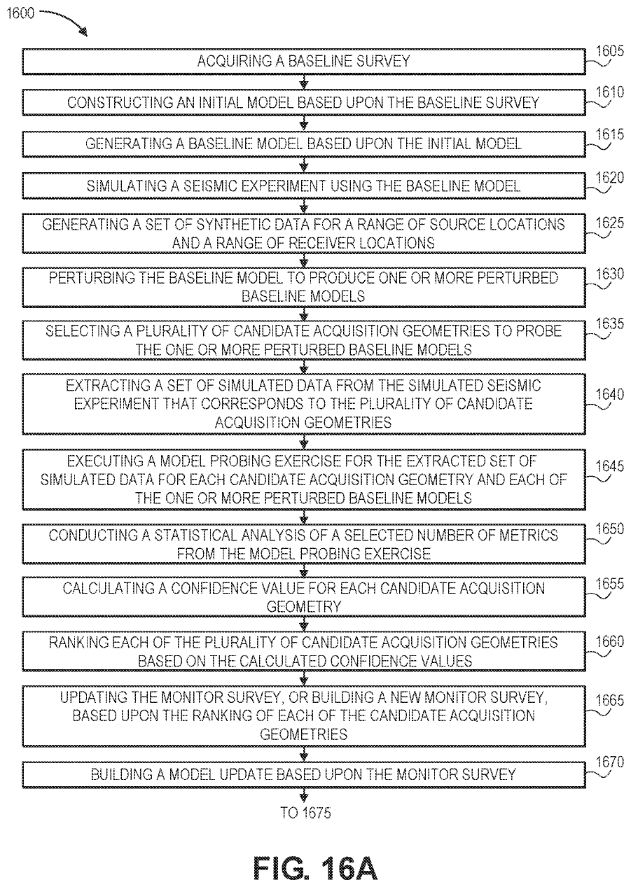

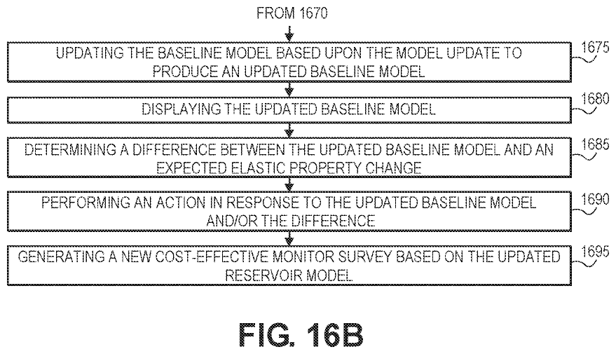

FIGS. 16A and 16B illustrate a flowchart of a method 1600 for monitoring subterranean hydrocarbon storage sites. An illustrative order of the method 1600 is provided below; however, one or more portions of the method 1600 may be performed in a different order, simultaneously, repeated, or omitted. At least a portion of the method 1600 may be performed using a computing system, such as system 100 of FIG. 1.

The method 1600 may include acquiring a baseline survey, as at 1605. The baseline survey may include a towed streamer survey, an ocean bottom node survey, a land seismic survey, a borehole seismic survey, or a combination thereof.

The method 1600 may also include constructing an initial model based upon the baseline survey, as at 1610. The initial model may be generated based upon legacy data, wellbore data, a tomographic model generated from the baseline survey, or a combination thereof.

The method 1600 may also include generating a baseline model based upon the initial model, as at 1615. The baseline model represents a P-wave velocity, an S-wave velocity, and/or density elastic properties of a subsurface formation before injection of CO₂ therein.

The method 1600 may also include simulating a seismic experiment using the baseline model, as at 1620. The seismic experiment may include a simulated pressure propagation of seismic wavefields and a simulated particle velocity propagation of the seismic wavefields in the baseline model.

The method 1600 may also include generating a set of synthetic data for a range of source locations and a range of receiver locations, as at 1625. The range of source locations and the range of receiver locations may correspond to an identified source location and an identified receiver location that respectively are configured to be used in a monitor survey. The source location and the receiver location may each be modelled first shot gathers or first receiver gathers. The first shot gathers and/or the first receivers gather respectively correspond to a single set or a multicomponent set of seismic data.

The method 1600 may also include perturbing the baseline model to produce one or more perturbed baseline models, as at 1630. The baseline model may be perturbed with a constant slowness to produce a first perturbed baseline model, and/or with a localized perturbation representative of a defined target to produce a second perturbed baseline model. The baseline model may be perturbed with a slowness value from about 0.5% to about 3% of an inverse P-wave velocity of the baseline model. The baseline model may be perturbed with the localized perturbation that corresponds to an expected elastic property change in the subsurface formation after the injection of CO₂. The expected elastic property change may be generated through reservoir modelling. The baseline model is perturbed in parallel with simulating the seismic experiment.

The method 1600 may also include selecting a plurality of candidate acquisition geometries to probe the one or more perturbed baseline models, as at 1635. The candidate acquisition geometries may include a subset of the identified source location and the identified receiver location.

The method 1600 may also include extracting a set of simulated data from the simulated seismic experiment that corresponds to the plurality of candidate acquisition geometries, as at 1640. The set of simulated data may include second shot gathers and/or second receiver gathers that each correspond to the source location and the receiver location in the plurality of candidate acquisition geometries.

The method 1600 may also include executing a model probing exercise for the extracted set of simulated data for each candidate acquisition geometry and each of the one or more perturbed baseline models, as at 1645. The model probing exercise may include calculating a data residual from the simulated seismic experiment and the one or more perturbed baseline models. The data residual may be or include a difference of an output of the simulated seismic experiment and the corresponding set of synthetic data generated in the one or more perturbed baseline models. The model probing exercise may also or instead include computing a full-waveform inversion gradient based upon the data residual. The full-waveform inversion gradient may be indicative of how the candidate acquisition geometries of the plurality of candidate acquisition geometries illuminates and recovers a target perturbation.

The method 1600 may also include conducting a statistical analysis of a selected number of metrics from the model probing exercise, as at 1650. The statistical analysis may include computing a mean and a standard deviation of the metrics. The metrics may include a percentage of a target region illuminated by a candidate acquisition geometry of the plurality of candidate acquisition geometries, a root mean square difference between the target perturbation and a recovered perturbation, a cross-correlation coefficient between the target perturbation and the recovered perturbation, an estimated cost of a candidate acquisition geometry of the plurality of candidate acquisition geometries, or a combination thereof.

The method 1600 may also include calculating a confidence value for each candidate acquisition geometry of the plurality of candidate acquisition geometries, as at 1655. The confidence value may be based upon the statistical analysis and/or the metrics.

The method 1600 may also include ranking each of the plurality of candidate acquisition geometries based on the calculated confidence values, as at 1660.

The method 1600 may also include updating the monitor survey, or building a new monitor survey, based upon the ranking of each of the candidate acquisition geometries of the plurality of candidate acquisition geometries, as at 1665. The updating monitor survey or building the new monitor survey may include acquiring a set of seismic data corresponding to a new source location and a new receiver location identified in a selected candidate acquisition geometry of the plurality of candidate acquisition geometries.

The method 1600 may also include building a model update based upon the monitor survey, as at 1670. The model update may include a full-waveform inversion update that identifies changes in the subsurface formation in a region of the expected elastic property change.

The method 1600 may also include updating the baseline model based upon the model update to produce an updated baseline model, as at 1675. The updated baseline model may represent the subsurface formation after CO₂ has been injected therein.

The method 1600 may also include displaying the updated baseline model, as at 1680.

The method 1600 may also include determining a difference between the updated baseline model and the expected elastic property change, as at 1685.

The method 1600 may also include performing an action in response to the updated baseline model and/or the difference between the updated baseline model and the expected elastic property change, as at 1690. The action may be or include generating an updated reservoir model based on the difference between the updated baseline model and the expected elastic property change. In another embodiment, the action may be or include generating and/or transmitting a signal that instructs or causes a physical action to occur. The physical action may address an unexpected CO₂ migration in the subsurface formation by changing the CO₂ injection strategy, injecting materials (such as gels or foams) into the well to prevent flow of CO₂, or the use of remediation techniques to address CO₂ migration within the well.

The method 1600 may also include generating a new cost-effective monitor survey based on the updated reservoir model, as at 1695.

The method 1600 may thus be used to determine that (1) the model update is in conformance with the reservoir model, (2) the model update is not in conformance with the reservoir model, and/or (3) the model update indicates a risk of a CO₂ leak. These outcomes may be reviewed and reported to the stakeholders, regulators, and/or subsurface operations. The scenario that is verified and the scale of deviation from the conformance scenario may define the subsurface or surface action. This may include, but is not limited to, performing the wellsite action.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to explain the principles of the invention and its practical applications, to thereby enable others skilled in the art to utilize the invention and various embodiments with various modifications as are suited to the particular use contemplated.

What is claimed is:

1. A method for monitoring subterranean hydrocarbon storage sites, the method comprising:
simulating a seismic experiment using a baseline model;
perturbing the baseline model to produce one or more perturbed baseline models;
selecting a plurality of candidate acquisition geometries to probe the one or more perturbed baseline models:
extracting a set of simulated data from the simulated seismic experiment that corresponds to the plurality of candidate acquisition geometries; and
executing a model probing exercise for the extracted set of simulated data for each candidate acquisition geometry and each of the one or more perturbed baseline models.

2. The method of claim 1, wherein the seismic experiment comprises a simulated propagation of seismic wavefields in the baseline model that may be extracted as a pressure and/or a particle velocity wavefield.

3. The method of claim 1, further comprising generating one or more sets of synthetic data for a range of source locations and a range of receiver locations that correspond to an identified source location and an identified receiver location.

4. The method of claim 3, wherein the candidate acquisition geometries comprise a subset of the identified source location and the identified receiver location.

5. The method of claim 3, wherein the set of simulated data comprises shot gathers and/or receiver gathers that each correspond to the identified source location and the identified receiver location.

6. The method of claim 1, wherein the baseline model is perturbed with a constant slowness value from about 0.5% to about 3% of an inverse P-wave velocity of the baseline model.

7. The method of claim 1, wherein the baseline model is perturbed with a localized perturbation representative of a defined target, wherein the localized perturbation corresponds to an expected elastic property change in a subsurface formation after injection of carbon dioxide (CO₂).

8. The method of claim 1, wherein the model probing exercise comprises determining a data residual from the simulated seismic experiment and the one or more perturbed baseline models, wherein the data residual comprises a difference between an output of the simulated seismic experiment and a corresponding set of synthetic data generated in the one or more perturbed baseline models.

9. The method of claim 8, wherein the model probing exercise further comprises determining a full-waveform inversion gradient based upon the data residual, wherein the full-waveform inversion gradient is indicative of how the candidate acquisition geometries illuminate and/or recover a target perturbation.

10. The method of claim 1, further comprising performing a wellsite action at least partially in response to an output of the model probing exercise.

11. A computing system, comprising:
one or more processors; and
a memory system comprising one or more non-transitory computer-readable media storing instructions that, when executed by at least one of the one or more processors, cause the computing system to perform operations, the operations comprising:
simulating a seismic experiment using a baseline model, wherein the seismic experiment comprises a simulated pressure propagation of seismic wavefields and/or a simulated particle velocity propagation of the seismic wavefields in the baseline model;
generating a set of synthetic data for a range of source locations and a range of receiver locations that correspond to an identified source location and an identified receiver location that respectively are configured to be used in a monitor survey;
perturbing the baseline model to produce one or more perturbed baseline models, wherein the baseline model is perturbed with a constant slowness to produce a first perturbed baseline model, and/or with a localized perturbation representative of a defined target to produce a second perturbed baseline model;
selecting a plurality of candidate acquisition geometries to probe the one or more perturbed baseline models, wherein the candidate acquisition geometries comprise a subset of the identified source location and the identified receiver location;
extracting a set of simulated data from the simulated seismic experiment that corresponds to the candidate acquisition geometries, wherein the set of simulated data comprises shot gathers and/or receiver gathers that each correspond to the identified source location and the identified receiver location in the candidate acquisition geometries; and
executing a model probing exercise for the extracted set of simulated data for each candidate acquisition geometry and each of the one or more perturbed baseline models.

12. The computing system of claim 11, wherein the model probing exercise comprises:
determining a data residual from the simulated seismic experiment and the one or more perturbed baseline models, wherein the data residual comprises a difference between an output of the simulated seismic experiment and the corresponding set of synthetic data generated in the one or more perturbed baseline models; and
determining a full-waveform inversion gradient based upon the data residual, wherein the full-waveform inversion gradient is indicative of how the candidate acquisition geometries illuminate and recover a target perturbation.

13. The computing system of claim 11, wherein the operations further comprise conducting a statistical analysis of a selected number of metrics from the model probing exercise, and wherein the metrics comprise a percentage of a target region illuminated by the candidate acquisition geometries, a root mean square difference between the target perturbation and a recovered perturbation, a cross-correlation coefficient between the target perturbation and the recovered perturbation, an estimated cost of the candidate acquisition geometries, or a combination thereof.

14. The computing system of claim 13, wherein the operations further comprise calculating a confidence value for each of the candidate acquisition geometries based upon the statistical analysis and/or the metrics.

15. The computing system of claim 14, wherein the operations further comprise ranking each of the plurality of candidate acquisition geometries based on the calculated confidence values.

16. A non-transitory computer-readable medium storing instructions that, when executed by one or more processors of a computing system, cause the computing system to perform operations, the operations comprising:
simulating a seismic experiment using a baseline model, wherein the seismic experiment comprises a simulated propagation of seismic wavefields that may be extracted as a pressure or a particle velocity measurement in the baseline model;
generating a set of synthetic data for a range of source locations and a range of receiver locations that correspond to an identified source location and an identified receiver location that respectively are configured to be used in a monitor survey, wherein the identified source location and the identified receiver location are each modelled first shot gathers or first receiver gathers, wherein the first shot gathers and/or the first receivers gather respectively correspond to a single set or a multicomponent set of seismic data;
perturbing the baseline model to produce one or more perturbed baseline models, wherein the baseline model is perturbed with a constant slowness to produce a first perturbed baseline model, and with a localized perturbation representative of a defined target to produce a second perturbed baseline model, wherein the baseline model is perturbed with a slowness value from about 0.5% to about 3% of an inverse P-wave velocity of the baseline model, wherein the baseline model is perturbed with the localized perturbation that corresponds to an expected elastic property change in a subsurface formation after injection of carbon dioxide (CO₂), wherein the expected elastic property change is generated through reservoir modelling, and wherein the baseline model is perturbed in parallel with simulating the seismic experiment;
selecting a plurality of candidate acquisition geometries to probe the one or more perturbed baseline models, wherein the candidate acquisition geometries comprise a subset of the identified source location and the identified receiver location;
extracting a set of simulated data from the simulated seismic experiment that corresponds to the candidate acquisition geometries, wherein the set of simulated data comprises second shot gathers and/or second receiver gathers that each correspond to the identified source location and the identified receiver location in the candidate acquisition geometries;
executing a model probing exercise for the extracted set of simulated data for each candidate acquisition geometry and each of the one or more perturbed baseline models, wherein the model probing exercise comprises:
determining a data residual from the simulated seismic experiment and the one or more perturbed baseline models, wherein the data residual comprises a difference between an output of the simulated seismic experiment and the corresponding set of synthetic data generated in the one or more perturbed baseline models; and
determining a full-waveform inversion gradient based upon the data residual, wherein the full-waveform inversion gradient is indicative of how the candidate acquisition geometries illuminate and recover a target perturbation;
conducting a statistical analysis of a selected number of metrics from the model probing exercise, wherein the statistical analysis comprises computing a mean and a standard deviation of the metrics, and wherein the metrics comprise a percentage of a target region illuminated by the candidate acquisition geometries, a root mean square difference between the target perturbation and a recovered perturbation, a cross-correlation coefficient between the target perturbation and the recovered perturbation, an estimated cost of the candidate acquisition geometries, or a combination thereof;
calculating a confidence value for each candidate acquisition geometry based upon the statistical analysis and/or the metrics; and
ranking each of the candidate acquisition geometries based on the calculated confidence values.

17. The operations of claim 16, wherein the operations further comprise:
acquiring a baseline survey, wherein the baseline survey comprises a towed streamer survey, an ocean bottom node survey, a land seismic survey, a borehole seismic survey, or a combination thereof;
constructing an initial model based upon the baseline survey, wherein the initial model is generated based upon legacy data, wellbore data, a tomographic model generated from the baseline survey, or a combination thereof; and
generating the baseline model based upon the initial model, wherein the baseline model represents a P-wave velocity, an S-wave velocity, and density elastic properties of a subsurface formation before injection of carbon dioxide (CO₂) therein.

18. The operations of claim 16, wherein the operations further comprise:
updating the monitor survey, or building a new monitor survey, based upon the ranking, wherein the updating monitor survey or building the new monitor survey comprises acquiring a set of seismic data corresponding to a new source location and a new receiver location identified in a selected candidate acquisition geometry of the plurality of candidate acquisition geometries;
building a model update based upon the monitor survey, wherein the model update comprises a full-waveform inversion update that identifies changes in the subsurface formation in a region of the expected elastic property change; and
updating the baseline model based upon the model update to produce an updated baseline model, wherein the updated baseline model represents the subsurface formation after the CO₂ has been injected therein.

19. The operations of claim 16, wherein the operations further comprise displaying the updated baseline model.

20. The operations of claim 16, wherein the operations further comprise:
determining a difference between the updated baseline model and the expected elastic property change; and
performing an action in response to the updated baseline model and/or the difference between the updated baseline model and the expected elastic property change, wherein the action comprises generating and/or transmitting a signal that instructs or causes a physical action to occur.
